(19) United States
(12) Patent Application Publication
(10) Pub. No.: US 2015/0028302 A1
(43) Pub. Date: Jan. 29, 2015

(54) ORGANIC LIGHT-EMITTING DISPLAY APPARATUS AND METHOD FOR MANUFACTURING ORGANIC LIGHT-EMITTING DISPLAY APPARATUS

(71) Applicant: Samsung Display Co., Ltd., Yongin-city (KR)

(72) Inventors: Il-Sang Lee, Yongin-city (KR); Sang-Wook Shin, Yongin-city (KR); Sun-Young Jung, Yongin-city (KR); Jin-Woo Park, Yongin-city (KR); Dong-Jin Kim, Yongin-city (KR)

(73) Assignee: Samsung Display Co., Ltd., Yongin-city (KR)

(21) Appl. No.: 14/257,562

(22) Filed: Apr. 21, 2014

(30) Foreign Application Priority Data
Jul. 25, 2013 (KR) 10-2013-0088267

(51) Int. Cl. H01L 51/52; H01L 27/32; C23C 14/08; H01L 51/56

(52) U.S. Cl. CPC H01L 51/5253; H01L 51/56; H01L 27/3244; C23C 14/08
USPC 257/40; 438/28; 204/298.13

(57) ABSTRACT

A method for manufacturing an organic light-emitting display apparatus including: forming an organic light-emitting device on a substrate, the organic light-emitting device including a first electrode, a second electrode, and an intermediate layer including at least an organic emission layer; and forming a thin film encapsulating layer on the organic light-emitting device, wherein the thin film encapsulating layer includes at least one inorganic film including a low temperature viscosity transition (LVT) inorganic material and an oxide, and the oxide includes zirconium-tungsten oxide or lithium-aluminum-silicon oxide.

### CROSS REFERENCE TO RELATED APPLICATION

This application claims priority from and the benefit of Korean Patent Application No. 10-2013-0088267, filed on Jul. 25, 2013, in the Korean Intellectual Property Office, which is hereby incorporated by reference for all purposes as if fully set for the herein.

### BACKGROUND

1. Field

Exemplary embodiments of the present invention relate to a method for manufacturing a sputtering target, an organic light-emitting display apparatus, and a method for manufacturing the organic light-emitting display apparatus.

2. Discussion of the Background

Recently, display apparatuses have been used in various ways. As the display apparatuses become slimmer and lighter, the use of the display apparatuses is increasing. An organic light-emitting display apparatus is a self-luminous display apparatus having low power consumption, a wide viewing angle, and a high image quality.

The organic light-emitting display apparatus includes an organic light-emitting device that includes a first electrode, a second electrode, and at least an organic emission layer disposed between the first electrode and the second electrode.

On the other hand, the organic light-emitting device is vulnerable to external moisture and heat. Therefore, there is a need for an encapsulating structure that encapsulates the organic light-emitting device.

As one of methods for forming the encapsulating structure, a sputtering method uses a sputtering target. However, it is difficult to form the encapsulating structure by using a sputtering. Consequently, there is a limitation in improving the durability and encapsulation characteristic of the organic light-emitting display apparatus.

The above information disclosed in this Background section is only for enhancement of understanding of the background of the invention and therefore it may contain information that does not form any part of the prior art nor what the prior art may suggest to a person of ordinary skill in the art.

### SUMMARY

Exemplary embodiments of the present invention provide a sputtering target comprising a low temperature viscosity transition (LVT) inorganic material.

Exemplary embodiments of the present invention also provides an organic light-emitting display apparatus including a thin film encapsulating layer to provide additional protection to on an organic light-emitting device, and a method for manufacturing the organic light-emitting display apparatus including a step forming the thin film encapsulating layer on the organic light-emitting device through sputtering process and heating process.

Additional features of the invention will be set forth in part in the description which follows and, in part, will be apparent from the description, or may be learned by practice of the presented embodiments.

An exemplary embodiment of the present invention discloses a sputtering target including a low temperature viscosity transition (LVT) inorganic material and zirconium-tungsten oxide or lithium-aluminum-silicon oxide.

An exemplary embodiment of the present invention discloses an organic light-emitting display apparatus including: a substrate; an organic light-emitting device disposed on the substrate, the organic light-emitting device including a first electrode, a second electrode, and an intermediate layer including at least an organic emission layer; and a thin film encapsulating layer disposed on the organic light-emitting device, wherein the thin film encapsulating layer includes at least one inorganic film including a low temperature viscosity transition (LVT) inorganic material and an oxide, and the oxide includes zirconium-tungsten oxide or lithium-aluminum-silicon oxide.

An exemplary embodiment of the present invention also discloses a method for manufacturing an organic light-emitting display apparatus including: forming an organic light-emitting device on a substrate, the organic light-emitting device including a first electrode, a second electrode, and an intermediate layer including at least an organic emission layer; and forming a thin film encapsulating layer on the organic light-emitting device, the thin film encapsulating layer including at least one inorganic film, wherein the inorganic film includes an LVT inorganic material and oxide, and the oxide includes zirconium-tungsten oxide or lithium-aluminum-silicon oxide.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a schematic perspective view of a sputtering target manufactured by a method according to an exemplary embodiment of the present invention;

FIG. 2 is a graph showing a thermal expansion coefficient of a material formed by a sputtering method using the sputtering target of FIG. 1;

FIG. 3 is a diagram illustrating a method for manufacturing an organic light-emitting display apparatus by using the sputtering target of FIG. 1;

FIG. 4 is a schematic cross-sectional view of the organic light-emitting display apparatus manufactured by the method of FIG. 3;

FIG. 5 is an enlarged view of a portion K of FIG. 4;

FIG. 6 is a schematic cross-sectional view of an organic light-emitting display apparatus according to another embodiment of the present invention; and

FIG. 7 is a schematic cross-sectional view of an organic light-emitting display apparatus according to another embodiment of the present invention.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

As used herein, the term “and/or” includes any and all combinations of one or more of the associated listed items. It will be also understood that for the purposes of this disclosure, “at least one of X, Y, and Z” can be construed as X only, Y only, Z only, or any combination of two or more items X, Y, and Z (e.g., XYZ, XYY, YZ, ZZ).

It will be understood that the terms “comprises” and/or “comprising” used herein specify the presence of stated features or components, but do not preclude the presence or addition of one or more other features or components.

It will be understood that when a layer, region, or component is referred to as being “formed on,” another layer, region, or component, it can be directly or indirectly formed on the other layer, region, or component. That is, for example, intervening layers, regions, or components may be present. It will be further understood that when an element or layer is referred to as being “on” or “connected to” another element or layer, it can be directly on or directly connected to the other element or layer, or intervening elements or layers may be present. In contrast, when an element or layer is referred to as being “directly on” or “directly connected to” another element or layer, there are no intervening elements or layers present.

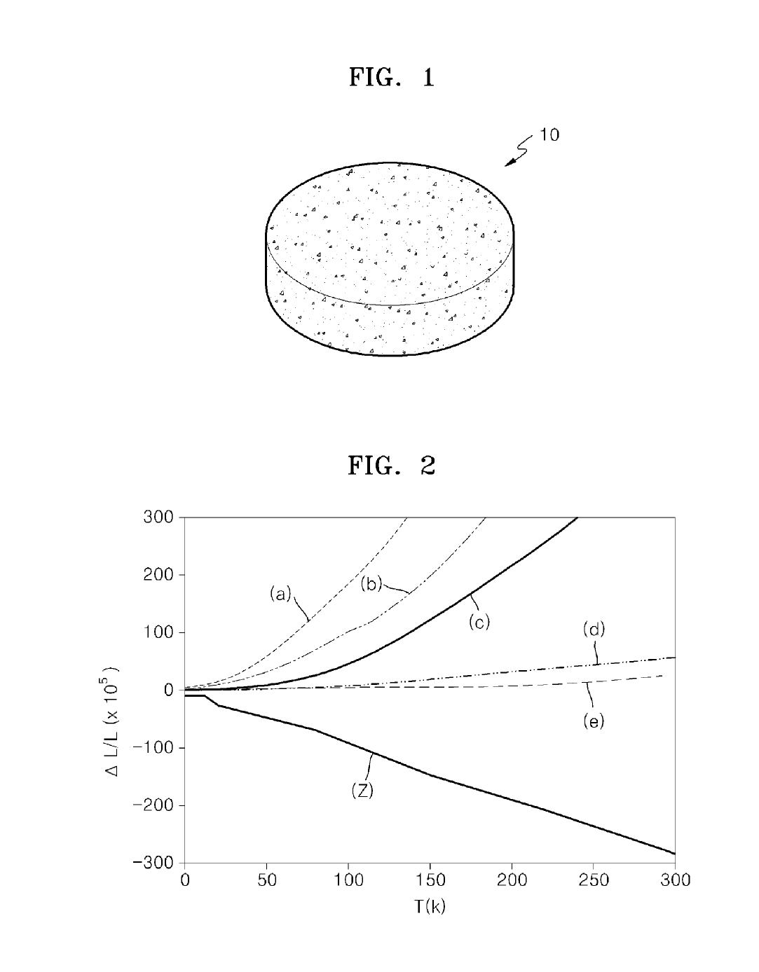

FIG. 1 is a schematic perspective view of a sputtering target manufactured by a method according to an embodiment of the present invention.

Referring to FIG. 1, an exemplary embodiment of the sputtering target 10 shows a shape of circular plate, but it is not limited thereto. The sputtering target 10 may have an angled shape or a pillar shape.

First exemplary embodiment of the sputtering target 10 may include a low temperature viscosity transition (LVT) inorganic material, zirconium oxide, and tungsten oxide. For example, the sputtering target 10 may include an LVT inorganic material, ZrO₂, and WO₃.

Second exemplary embodiment of the sputtering target 10 may include an LVT inorganic material, silicon oxide, lithium oxide, and aluminum oxide. For example, the sputtering target 10 may include an LVT inorganic material, SiO₂, Li₂O, and Al₂O₃.

Third exemplary embodiment of the sputtering target 10 may include an LVT inorganic material, zirconium oxide, tungsten oxide, silicon oxide, lithium oxide, and aluminum oxide. For example, the sputtering target 10 may include an LVT inorganic material, ZrO₂, WO₃, SiO₂, Li₂O, and Al₂O₃.

Fourth exemplary embodiment of the sputtering target 10 may include an LVT inorganic material, zirconium oxide, and tungsten. For example, the sputtering target 10 may include an LVT inorganic material, ZrO₂, and W. In the current exemplary embodiment, the sputtering target 10 includes metal tungsten, not tungsten oxide. By including metal tungsten, the electrical resistance of the sputtering target 10 may be reduced during the sputtering process, and the efficiency of the sputtering process may be improved.

Fifth exemplary embodiment of the sputtering target 10 may include an LVT inorganic material, silicon oxide, lithium, and aluminum oxide, or may include an LVT inorganic material, silicon oxide, lithium oxide, and aluminum, or may include an LVT inorganic material, silicon oxide, lithium, and aluminum. In other words, either one of lithium or aluminum in the sputtering target 10 exists in a metal form rather than an oxide state. For example, the sputtering target 10 may include an LVT inorganic material, SiO₂, Li₂O, and Al. By including either one of lithium or aluminum in metal state, the electrical resistance of the sputtering target 10 may be reduced, and the efficiency of the sputtering process may be improved.

Sixth exemplary embodiment of the sputtering target 10 may include an LVT inorganic material, zirconium oxide, tungsten, silicon oxide, lithium, and aluminum. In the current exemplary embodiment, at least one of tungsten, lithium, and aluminum in the sputtering target 10 exists in a metal form rather than an oxide form. For example, the sputtering target 10 may include an LVT inorganic material, ZrO₂, W, SiO₂, Li₂O, and Al. By including at least one of tungsten, lithium, and aluminum in metal form, the electrical resistance of the sputtering target 10 may be reduced, and the efficiency of the sputtering process may be improved.

The term “viscosity transition temperature” used herein refers to a minimum temperature at which fluidity may be provided to the LVT inorganic material. In other words, viscosity transition temperature refers to a minimum temperature at which a viscosity of the LVT inorganic material changes.

In one exemplary embodiment, the viscosity transition temperature of the LVT inorganic material may be about 80° C. or higher, more specifically but not limited to, in the range of about 80° C. to about 132° C. For example, the viscosity transition temperature of the LVT inorganic material may be about 80° C. to about 120° C., or about 100° C. to about 120° C. The viscosity transition temperature of the LVT inorganic material may also be about 110° C.

The LVT inorganic material may be a single compound or a mixture of two or more kinds of compounds.

The LVT inorganic material may include tin oxide (for example, SnO or SnO₂). In one exemplary embodiment, the LVT inorganic material may include about 20 wt % to about 100 wt % of SnO. The LVT inorganic material may further include at least one of phosphorus oxide (for example, P₂O₅), boron phosphate (BPO₄), tin fluoride (for example, SnF₂), niobium oxide (for example, NbO), and tungsten oxide (for example, WO₃).

For example, the LVT inorganic material may include, but is not limited to:

SnO;

SnO and P₂O₅;

SnO and BPO₄;

SnO, SnF₂, and P₂O₅;

SnO, SnF₂, P₂O₅, and NbO; or

SnO, SnF₂, P₂O₅, and WO₃.

The sputtering target 10 may be manufactured using various methods. According to one embodiment of the present invention, the sputtering target 10 may be manufactured by preparing a powder including an LVT inorganic material, ZrO₂, and WO₃, uniformly mixing the power, melting the mixed powder at a high temperature and a high pressure, pressurizing the molten material, cooling the pressurized material, and cutting the cooled material.

FIG. 2 is a graph showing a thermal expansion coefficient of a material formed by a sputtering method using the sputtering target of FIG. 1.

Referring to FIG. 2, the graph distinguishes the thermal expansion coefficient of ZrW₂O₈ from other materials. In current exemplary embodiment, the ZrW₂O₈ may be formed by performing a sputtering process on the sputtering target 10 including an LVT inorganic material, zirconium oxide, and tungsten oxide, or by performing a sputtering process in an oxygen-containing atmosphere by using the sputtering target 10 including an LVT inorganic material, zirconium oxide, and tungsten.

Referring to FIG. 2, the X axis represents temperature, and the Y axis represents thermal expansion coefficient. Each line graph (a), (b), (c), (d), (e), and (z) represents thermal expansion coefficient of an epoxy material, an ice, aluminum, Invar, silicon, and ZrW₂O₈, respectively.

As the line graph (z) represents, the ZrW₂O₈ has negative (−) thermal expansion coefficient. It is much lower compared to the high thermal expansion coefficient of the LVT inorganic material. Therefore, if the sputtering target 10 may be used in forming a thin film encapsulating layer, it may be possible to prevent damage to the thin film encapsulating layer due to high thermal expansion coefficient of the LVT inorganic material.

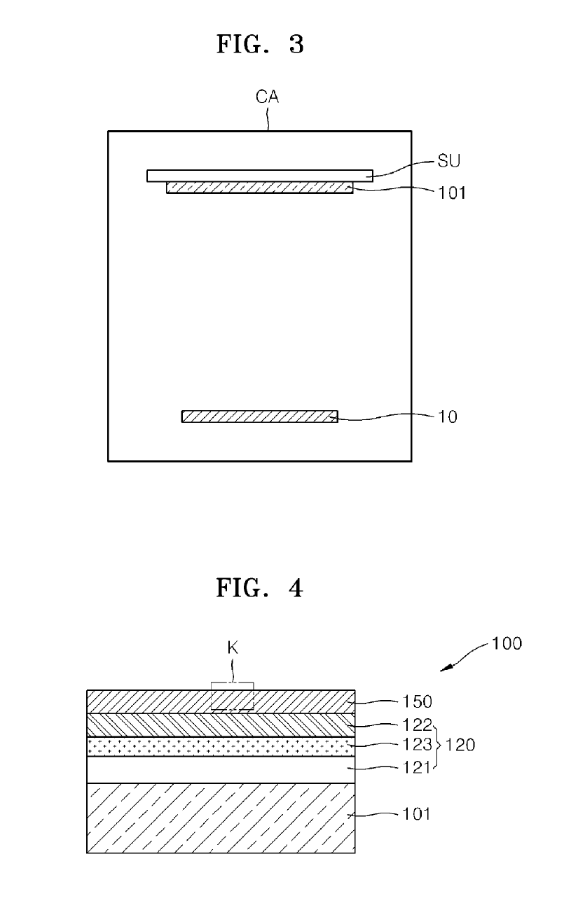

FIG. 3 is a diagram illustrating a method for manufacturing an organic light-emitting display apparatus by using the sputtering target of FIG. 1.

Referring to FIG. 3, the above-described sputtering target 10 and a substrate 101 are disposed within a chamber CA. The substrate 101 is disposed on a stage unit SU, and the sputtering target 10 is disposed to face the substrate 101. By performing a sputtering process using the sputtering target 10, a thin film of material from the sputtering target 10 may be formed on the substrate 101. In other words, a thin film encapsulating layer may be formed on the substrate 101.

The structure illustrated in FIG. 3 is an exemplary embodiment of the present invention. In other words, an organic light-emitting display apparatus may be manufactured by performing various sputtering methods using the sputtering target 10.

For instance, in another exemplary embodiment, two sputtering targets 10 may be disposed to face each other, and plasma may be generated in a space between the two sputtering targets 10. In the current embodiment, it may be possible to prevent damage to the substrate 101 from direct collision of particles.

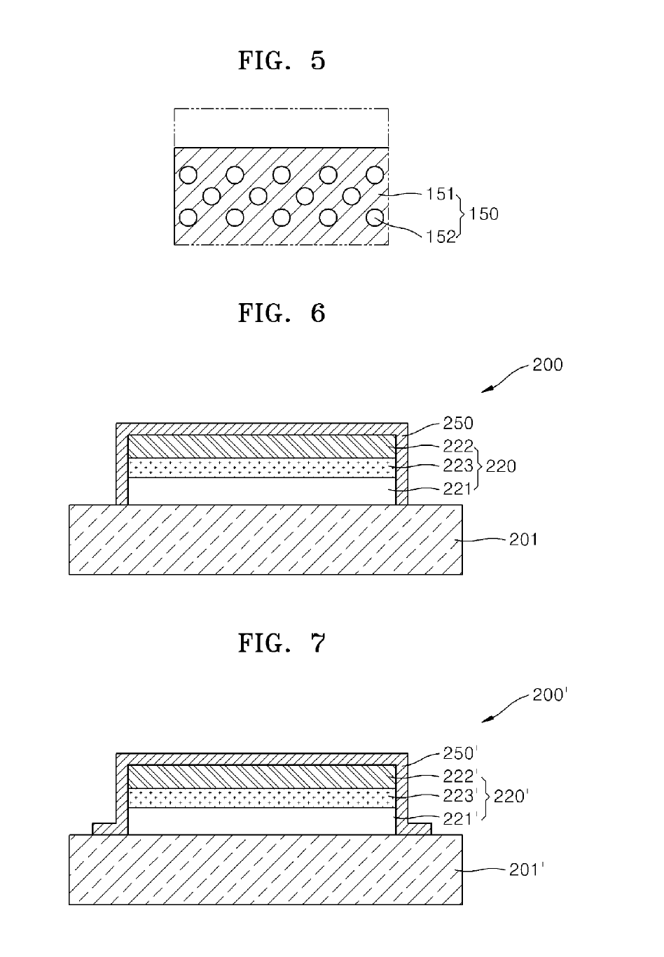

FIG. 4 is a schematic cross-sectional view of the organic light-emitting display apparatus manufactured by the method of FIG. 3. FIG. 5 is an enlarged view of a portion K of FIG. 4.

Referring to FIG. 4, the organic light-emitting display apparatus 100 may include a substrate 101, an organic light-emitting device 120, and a thin film encapsulating layer 150 including at least one inorganic film including an LVT inorganic material.

The substrate 101 may be made of various materials. For example, the substrate 101 may be formed made of transparent glass material including SiO₂, or transparent plastic material.

The organic light-emitting device 120 disposed on the substrate 101 includes a first electrode 121, a second electrode 122, and an intermediate layer 123. The first electrode 121 is disposed on the substrate 101, the second electrode 122 is disposed on the first electrode 121, and the intermediate layer 123 is disposed between the first electrode 121 and the second electrode 122.

A buffer layer may be further disposed between the first electrode 121 and the substrate 101. The buffer layer may provide a flat surface on the substrate 101 to prevent moisture and gas from penetrating into the organic light-emitting device 120 through the substrate 101.

The first electrode 121 may function as an anode, and the second electrode 122 may function as a cathode. The polarities of the electrodes 121 and 122 are interchangeable.

When the first electrode 121 functions as an anode, the first electrode 121 may include indium tin oxide (ITO), indium zinc oxide (IZO), zinc oxide (ZnO), or indium oxide (In₂O₃) having a high work function. Depending on the purpose and design condition, the first electrode 121 may further include a reflection film including silver (Ag), magnesium (Mg), aluminum (Al), platinum (Pt), palladium (Pd), gold (Au), nickel (Ni), neodymium (Nd), iridium (Ir), chromium (Cr), lithium (Li), ytterbium (Yb), or calcium (Ca).

When the second electrode 122 functions as the cathode, the second electrode 122 may be formed of a metal such as Ag, Mg, Al, Pt, Pd, Au, Ni, Nd, Ir, Cr, Li, or Ca. The second electrode 122 may further include a light transmission material, such as ITO, IZO, ZnO, or In₂O₃.

The intermediate layer 123 includes at least one organic emission layer. The intermediate layer 123 may further include at least one of a hole injection layer, a hole transport layer, an electron transport layer, and an electron injection layer.

When voltage is applied between the first electrode 121 and the second electrode 122, visible light is generated from the organic emission layer of the intermediate layer 123.

According to an exemplary embodiment of the present invention, the organic light-emitting display apparatus 100 may include at least one thin film transistor electrically connected to the organic light-emitting device 120. The organic light-emitting display apparatus 100 may include at least one capacitor electrically connected to the organic light-emitting device 120.

Furthermore, at least one planarization layer or at least one protection layer may be provided between the organic light-emitting device 120 and the thin film encapsulating layer 150. The planarization layer or the protection layer provides a flat surface on the organic light-emitting device 120 to protect the organic light-emitting device 120. The planarization layer or the protection layer may be made of various insulating materials. For example, the planarization layer or the protection layer may be made of an organic material.

Referring to FIG. 5, the thin film encapsulating layer 150 is provided on the organic light-emitting device 120. The thin film encapsulating layer 150 includes an LVT inorganic material 151 and at least one kind of oxide 152.

For example, the oxide 152 may include zirconium-tungsten oxide, such as ZrW₂O₈, or Zr₂WP₂O₁₂. The oxide 152 may also include lithium-aluminum-silicon oxide, such as LiAlSiO4. The oxide 152 may include both zirconium-tungsten oxide and lithium-aluminum-silicon oxide.

Referring to FIGS. 3 and 5, the thin film encapsulating layer 150 may be formed by a sputtering method using the sputtering target 10. The method of forming the thin film encapsulating layer 150 will be described below.

First, the substrate 101 is placed in the chamber CA at which the sputtering target 10 is disposed. The organic light-emitting device 120 may be disposed on the substrate 101. The planarization layer or the protection layer may further be disposed on the organic light-emitting device 120. Then, a preliminary thin film encapsulating layer may be formed by sputtering process using the sputtering target 10. The preliminary thin film encapsulating layer will later be formed into the thin film encapsulating layer 150 by a heating process.

In the first exemplary embodiment where the sputtering target 10 includes an LVT inorganic material, zirconium oxide, and tungsten oxide, the preliminary thin film encapsulating layer formed by sputtering process using the sputtering target 10 may include an LVT inorganic material and zirconium-tungsten oxide. The zirconium-tungsten oxide may include ZrW₂O₈, or Zr₂WP₂O₁₂. Zr₂WP₂O₁₂ may be formed from a reaction between zirconium-tungsten oxide and phosphorus oxide included in the LVT inorganic material.

In the second exemplary embodiment where the sputtering target 10 includes an LVT inorganic material, silicon oxide, lithium oxide, and aluminum oxide, the preliminary thin film encapsulating layer formed by a sputtering process using the sputtering target 10 may include an LVT inorganic material and lithium-aluminum-silicon oxide. The lithium-aluminum-silicon oxide may include LiAlSiO₄.

In the third exemplary embodiment where the sputtering target 10 includes an LVT inorganic material, zirconium oxide, tungsten oxide, silicon oxide, lithium oxide, and aluminum oxide, the preliminary thin film encapsulating layer formed by a sputtering process using the sputtering target 10 may include an LVT inorganic material, lithium-aluminum-silicon oxide, and zirconium-tungsten oxide. The lithium-aluminum-silicon oxide may include LiAlSiO₄, and the zirconium-tungsten oxide may include ZrW₂O₈ or Zr₂WP₂O₁₂.

In the fourth exemplary embodiment where the sputtering target 10 includes an LVT inorganic material, zirconium oxide, and tungsten, the preliminary thin film encapsulating layer formed by a sputtering process using the sputtering target 10 in an oxygen atmosphere may include an LVT inorganic material and zirconium-tungsten oxide. The zirconium-tungsten oxide may include ZrW₂O₈ or Zr₂WP₂O₁₂. The sputtering process is performed in an oxygen atmosphere in order to oxidize the metal tungsten. The electrical resistance of the tungsten-containing sputtering target 10 may be reduced, and the speed of the sputtering process may be increased.

In the fifth exemplary embodiment where the sputtering target 10 includes an LVT inorganic material, silicon oxide, lithium, and aluminum oxide, or the sputtering target 10 includes an LVT inorganic material, silicon oxide, lithium oxide, and aluminum, or the sputtering target 10 includes an LVT inorganic material, silicon oxide, lithium, and aluminum, the preliminary thin film encapsulating layer formed by a sputtering process using the sputtering target 10 in an oxygen atmosphere may include an LVT inorganic material and lithium-aluminum-silicon oxide. The lithium-aluminum-silicon oxide may include LiAlSiO4. The sputtering process is performed in an oxygen atmosphere in order to oxidize the metal lithium or aluminum. The electrical resistance of the metal-containing sputtering target 10 may be reduced, and the speed of the sputtering process may be increased.

In the sixth exemplary embodiment, where the sputtering target 10 may include an LVT inorganic material, zirconium oxide, tungsten, silicon oxide, lithium, and aluminum, wherein at least one of tungsten, lithium, and aluminum in the sputtering target 10 exists in a metal form, the preliminary thin film encapsulating layer formed by a sputtering process using the sputtering target 10 in an oxygen atmosphere may include an LVT inorganic material, lithium-aluminum-silicon oxide, and zirconium-tungsten oxide. The lithium-aluminum-silicon oxide may include LiAlSiO4. The zirconium-tungsten oxide may include ZrW₂O₈ or Zr₂WP₂O₁₂. The sputtering process is performed in an oxygen atmosphere in order to oxidize the metal tungsten, lithium or aluminum. The electrical resistance of the metal-containing sputtering target 10 may be reduced, and the speed of the sputtering process may be increased.

The preliminary thin film encapsulating layer formed by the sputtering process may include various defects such as an environmental component, a film-formation component, and a pinhole. The environmental component may be either an organic material or an inorganic material. The environmental component refers to particles attached during one of a plurality of processes of forming the organic light-emitting display apparatus, and it may create a void space between the preliminary thin film encapsulating layer and the organic light-emitting device 120. The film-formation component refers to aggregate particles of the LVT inorganic material that does not contribute to the formation of the preliminary thin film encapsulating layer. The pinhole refers to a region where the LVT inorganic material is not provided.

The above-described defects of the preliminary thin film encapsulating layer may let external environmental materials, for example, moisture or oxygen to penetrate. This may cause progressive dark spots, which may reduce the life of the organic light-emitting display apparatus 100.

Therefore, after the formation of the preliminary thin film encapsulating layer, a heating process is required to form the thin film encapsulating layer 150 as illustrated in FIGS. 4 and 5.

The heating process is performed at a higher temperature than a viscosity transition temperature of the LVT inorganic material. The heating process may be performed by annealing the preliminary thin film encapsulating layer at the temperature range from the viscosity transition temperature of the LVT inorganic material to a metamorphic temperature of the material of the intermediate layer 123. When intermediate layer 123 includes more than one material, the heating process may be performed by annealing the preliminary thin film encapsulating layer at the temperature range from the viscosity transition temperature of the LVT inorganic material to the minimum metamorphic temperature among the materials included in the intermediate layer 123. The heating process may also be performed at the viscosity transition temperature of the LVT inorganic material.

For example, the heating process may be performed by annealing the preliminary thin film encapsulating layer at the temperature range of about 80° C. to about 132° C. more specifically, about 100° C. to about 120° C.) for about one hour to about three hours (more specifically, at about 110° C. for about two hours), but is not limited thereto.

Through the heating process within the temperature range, the LVT inorganic material of the preliminary thin film encapsulating layer may be fluidized to prevent the degeneration in the intermediate layer 123 of the organic light-emitting device 120. To prevent exposure to external environment through the pinhole of the preliminary thin film encapsulating layer, the heating process may be performed in an IR oven under a vacuum state or an inert gas atmosphere, such as N₂ atmosphere or Ar atmosphere.

The fluidized LVT inorganic material included in the preliminary thin film encapsulating layer may have flowability. Therefore, through the heating process, the fluidized LVT inorganic material may fill the void space formed by the environmental component, and the pinhole. Also, the film-formation component may become fluidized and fill the pinhole.

In an alternative exemplary embodiment, the heat resistance and mechanical strength of the thin film encapsulating layer 150 may be improved by performing the heating process two times.

The viscosity transition temperature of the LVT inorganic material 151 may be lower than the metamorphic temperature of the material included in the intermediate layer 123. When intermediate layer 123 includes more than one material, the viscosity transition temperature of the LVT inorganic material 151 may be lower than the minimum metamorphic temperature among the material included in the intermediate layer 123.

The metamorphic temperature of the intermediate layer 123 refers to a temperature that may cause a physical and/or chemical metamorphosis of the material included in the intermediate layer 123. A plurality of metamorphic temperatures may be present depending on type and number of the materials included in the intermediate layer 123. According to one of the exemplary embodiments, the viscosity transition temperature of the LVT inorganic material 151 and the metamorphic temperature of the intermediate layer 123 may each refer to a glass transition temperature (Tg) of the LVT inorganic material and a glass transition temperature (Tg) of an organic material included in the intermediate layer 123, respectively.

The glass transition temperature (Tg) may be measured by performing a Thermo Gravimetric Analysis (TGA) on the organic material included in the LVT inorganic material 151 and the intermediate layer 123. For example, the glass transition temperature may be derived from a thermal analysis using a TGA and a Differential Scanning Calorimetry (DSC) with respect to the material included in the intermediate layer 123 (N₂ atmosphere, temperature range: room temperature to about 600° C. (10° C./min)-TGA, room temperature to about 400° C.-DSC, pan type: Pt pan in disposable Al Pan (TGA), disposable Al pan (DSC)), which could easily be measured by any person having ordinary skill in the art.

The metamorphic temperature of the material included in the intermediate layer 123 may exceed, but not limited to, about 130° C. The minimum metamorphic temperatures among the material included in the intermediate layer 123 may be about 130° C. to about 140° C. The minimum value among the metamorphic temperatures of the material included in the intermediate layer 123 may be, but not limited to, about 132° C. As described above, the minimum metamorphic temperatures among the material included in the intermediate layer 123 may be obtained by selecting the minimum value among the various Tg values from TGA.

In one exemplary embodiment, the viscosity transition temperature of the LVT inorganic material 151 may be about 80° C. or higher, more specifically but not limited to, in the range of about 80° C. to about 132° C., but is not limited thereto. For example, the viscosity transition temperature of the LVT inorganic material 151 may be about 80° C. to about 120° C., or about 100° C. to about 120° C. The viscosity transition temperature of the LVT inorganic material 151 may be about 110° C.

The LVT inorganic material 151 may include tin oxide (for example, SnO or SnO₂). In one exemplary embodiment, the LVT inorganic material 151 may include about 20 wt % to about 100 wt % of SnO.

The LVT inorganic material 151 may further include at least one of phosphorus oxide (for example, P₂O₅), boron phosphate (BPO₄), tin fluoride (for example, SnF₂), niobium oxide (for example, NbO), and tungsten oxide (for example, WO₃), but is not limited thereto.

For example, the LVT inorganic material may 151 include, but is not limited to:

SnO;

SnO and P₂O₅;

SnO and BPO₄;

SnO, SnF₂, and P₂O₅;

SnO, SnF₂, P₂O₅, and NbO; or

SnO, SnF₂, P₂O₅, and WO₃.

The LVT inorganic material 151 may have the following composition, but is not limited thereto:

1) SnO (100 wt %);

2) SnO (80 wt %) and P₂O₅ (20 wt %);

3) SnO (90 wt %) and BPO₄ (10 wt %);

4) SnO (20-50 wt %), SnF₂ (30-60 wt %), and P₂O₅ (10-30 wt %) (wherein the total weight of SnO, SnF₂, and P₂O₅ is 100 wt %);

5) SnO (20-50 wt %), SnF₂ (30-60 wt %), P₂O₅ (10-30 wt %), and NbO (1-5 wt %) (wherein the total weight of SnO, SnF₂, P₂O₅, and NbO is 100 wt %); or

6) SnO (20-50 wt %), SnF₂ (30-60 wt %), P₂O₅ (10-30 wt %), and WO₃ (1-5 wt %) (wherein the total weight of SnO, SnF₂, P₂O₅, and WO₃ is 100 wt %).

In one exemplary embodiment, the LVT inorganic material 151 may include SnO (42.5 wt %), SnF₂ (40 wt %), P₂O₅ (15 wt %), and WO₃ (2.5 wt %). Various compositions of the LVT inorganic material 151 may be adjusted by controlling the inorganic material composition of the sputtering target 10, the pressure and temperature condition of the sputtering process, and kind of gas forming the sputtering process atmosphere.

According to the exemplary embodiments of the organic light-emitting display apparatus 100, the organic light-emitting device 120 is encapsulated by the thin film encapsulating layer 150. Furthermore, the organic light-emitting display apparatus 100 may have enhanced flexibility by minimizing the thickness of the thin film encapsulating layer 150.

The thin film encapsulating layer 150 may include the LVT inorganic material 151 and the oxide 152, and the oxide 152 may include zirconium-tungsten oxide or lithium-aluminum-silicon oxide. The LVT inorganic material 151 may have flowability at a relatively low temperature. Therefore, the LVT inorganic material 151 may cover the film-formation component and the environmental component during the heating process, and encapsulate the organic light-emitting device 120. However, the LVT inorganic material 151 has a relatively high thermal expansion coefficient. Since heating process is a thermal treatment, structural stress may be created from rapid expansion and shrinkage caused by the heating process. This risk can be minimized by including the zirconium-tungsten oxide or the lithium-aluminum-silicon oxide in the oxide 152, since the zirconium-tungsten oxide or the lithium-aluminum-silicon oxide has low or negative thermal expansion coefficient, reducing the rapid expansion and shrinkage of the LVT inorganic material 151, and suppressing structural stress. In conclusion, the durability of the thin film encapsulating layer 150 may be improved, and the encapsulation characteristic of the organic light-emitting display apparatus 100 may also be improved. For example, ZrW₂O₈, Zr₂WP₂O₁₂, or LiAlSiO₄ has a very low thermal expansion coefficient.

Moreover, the thin film encapsulating layer 150 may be formed by a sputtering process using a single sputtering target 10 that includes materials for forming the LVT inorganic material 151, as well as the materials for forming the oxide 152 including the zirconium-tungsten oxide or the lithium-aluminum-silicon oxide. Therefore, the thin film encapsulating layer 150 having a desired characteristic may easily be manufactured without complicated processes. However, the number of sputtering target used in the sputtering process is not limited to one, and more than 2 sputtering targets may be used.

Additionally, when metal, such as tungsten, lithium, and aluminum, is included in the sputtering target 10 instead of its oxide forms, such as tungsten oxide, lithium oxide, and aluminum oxide, the electrical resistance of the sputtering target 10 may be reduced, and the processing time of the sputtering process may be reduced.

FIG. 6 is a schematic cross-sectional view of an organic light-emitting display apparatus according to another embodiment of the present invention.

Referring to FIG. 6, the organic light-emitting display apparatus 200 includes a substrate 201, an organic light-emitting device 220, and a thin film encapsulating layer 250. The organic light-emitting device 220 includes a first electrode 221, a second electrode 222, and an intermediate layer 223 disposed between the first electrode 221 and the second electrode 222.

In comparison with the embodiment illustrated in the FIG. 3, the thin film encapsulating layer 250 of current exemplary embodiment is configured to cover a top surface and a side of the organic light-emitting device 220, contacting the substrate 201. Therefore, the thin film encapsulating layer 250 is completely encapsulating the organic light-emitting device 220. The current exemplary embodiment may provide additional protection for the organic light-emitting device 220 against the damages from moisture, external gas, and foreign substances penetrating from the side of the organic light emitting device 220. Additionally, since the thin film encapsulating layer 250 contacts the substrate 201, the thin film encapsulating layer 250 may not be peeled off easily from the organic light-emitting display apparatus 200, enhancing the durability of the thin film encapsulating layer 250. In other exemplary embodiment, the thin film encapsulating layer 250 may also be contacting an insulating film or a conductive film which may be additionally formed on the top surface of the substrate 201 and under the bottom surface of the organic light-emitting display apparatus 200.

The materials used to form the organic light-emitting device 220 and the thin film encapsulating layer 250 are substantially identical to the organic light-emitting device 120 and the thin film encapsulating layer 150, respectively.

FIG. 7 is a schematic cross-sectional view of an organic light-emitting display apparatus according to another embodiment of the present invention.

Referring to FIG. 7, the organic light-emitting display apparatus 200′ includes a substrate 201′, an organic light-emitting device 220′, and a thin film encapsulating layer 250′. The organic light-emitting device 220′ includes a first electrode 221′, a second electrode 222′, and an intermediate layer 223′ disposed between the first electrode 321 and the second electrode 322.

In comparison with the embodiment illustrated in the FIG. 6, the thin film encapsulating layer 250′ of current exemplary embodiment further extends outward, increasing the contact surface with the substrate 201′. The increased contact surface between the thin film encapsulating layer 250′ and the substrate 201′ may effectively prevent moisture, gas and foreign substances from penetrating through any potential gap between the thin film encapsulating layer 250′ and the substrate 201′. Additionally, since connection between the thin film encapsulating layer 250′ and the substrate 201′ may be more stabilized, the durability of the thin film encapsulating layer 250′ and the organic light-emitting display apparatus 200′ may be further improved.

The materials used to form the organic light-emitting device 220′ and the thin film encapsulating layer 250′ are substantially identical the organic light-emitting device 120 and the thin film encapsulating layer 150, respectively.

According to the provided exemplary embodiments of the present invention, the method for manufacturing the sputtering target, the organic light-emitting display apparatus, and the method for manufacturing the organic light-emitting display apparatus may improve the durability and encapsulation characteristic of the organic light-emitting display apparatus.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims.

What is claimed is:

1. A sputtering target comprising a low temperature viscosity transition (LVT) inorganic material, and zirconium-tungsten oxide or lithium-aluminum-silicon oxide.

2. The sputtering target of claim 1, wherein the LVT inorganic material comprises tin oxide.

3. The sputtering target of claim 1, wherein the sputtering target comprises zirconium-tungsten oxide comprising zirconium oxide and tungsten, or zirconium oxide and tungsten oxide.

4. The sputtering target of claim 1, wherein the sputtering target comprises lithium-aluminum-silicon oxide comprising silicon oxide, lithium, and aluminum, or silicon oxide, lithium oxide, and aluminum, or silicon oxide, lithium, and aluminum oxide, or silicon oxide, lithium oxide, and aluminum oxide.

5. An organic light-emitting display apparatus comprising:
a substrate;
an organic light-emitting device disposed on the substrate, the organic light-emitting device comprising a first electrode, a second electrode, and an intermediate layer comprising at least an organic emission layer; and
a thin film encapsulating layer disposed on the organic light-emitting device, wherein the thin film encapsulating layer comprises at least one inorganic film comprising a low temperature viscosity transition (LVT) inorganic material and an oxide, and the oxide comprises zirconium-tungsten oxide or lithium-aluminum-silicon oxide.

6. The organic light-emitting display apparatus of claim 5, wherein the oxide comprises zirconium-tungsten oxide, and the zirconium-tungsten oxide comprises ZrW₂O₈ or Zr₂WP₂O₁₂.

7. The organic light-emitting display apparatus of claim 5, wherein the oxide comprises lithium-aluminum-silicon oxide, and the lithium-aluminum-silicon oxide comprises LiAlSiO₄.

8. The organic light-emitting display apparatus of claim 5, wherein the LVT inorganic material comprises tin oxide.

9. The organic light-emitting display apparatus of claim 8, wherein the LVT inorganic material further comprises at least one of phosphorus oxide, boron phosphate, tin fluoride, niobium oxide, and tungsten oxide.

10. The organic light-emitting display apparatus of claim 5, wherein a viscosity transition temperature of the LVT inorganic material is lower than a metamorphic temperature of a material included in the intermediate layer of the organic light-emitting device.

11. The organic light-emitting display apparatus of claim 5, wherein the thin film encapsulating layer covers a top surface and a side of the organic light-emitting device.

12. The organic light-emitting display apparatus of claim 11, wherein the thin film encapsulating layer further extends onto the surface of the substrate.

13. A method for manufacturing an organic light-emitting display apparatus, the method comprising:
forming an organic light-emitting device on a substrate, the organic light-emitting device comprising a first electrode, a second electrode, and an intermediate layer comprising at least an organic emission layer; and
forming a thin film encapsulating layer on the organic light-emitting device, wherein the thin film encapsulating layer comprises at least one inorganic film
comprising a low temperature viscosity transition (LVT) inorganic material and an oxide, and the oxide comprises zirconium-tungsten oxide or lithium-aluminum-silicon oxide.

14. The method of claim 13, wherein the forming of the thin film encapsulating layer further comprises a sputtering process.

15. The method of claim 14, wherein the sputtering process further comprises using a sputtering target that comprises an LVT inorganic material comprising tin oxide.

16. The method of claim 15, wherein the sputtering target comprises zirconium-tungsten oxide comprising zirconium oxide and tungsten, or zirconium oxide and tungsten oxide.

17. The method of claim 15, wherein when the sputtering target comprises zirconium-tungsten oxide comprising zirconium oxide and tungsten, and the sputtering process is performed in an oxygen atmosphere.

18. The method of claim 15, wherein the sputtering target comprises lithium-aluminum-silicon oxide comprising silicon oxide, lithium, and aluminum, or silicon oxide, lithium oxide, and aluminum, or silicon oxide, lithium, and aluminum oxide, or silicon oxide, lithium oxide, and aluminum oxide.

19. The method of claim 15, wherein the sputtering target comprises lithium-aluminum-silicon oxide comprising silicon oxide, lithium, and aluminum, or silicon oxide, lithium oxide, and aluminum, or silicon oxide, lithium, and aluminum oxide, and the sputtering process is performed in an oxygen atmosphere.

20. The method of claim 13, wherein the forming of the thin film encapsulating layer further comprises:
forming a preliminary thin film encapsulating layer including the LVT inorganic material; and
heating the preliminary thin film encapsulating layer by annealing the preliminary thin film encapsulating layer at the temperature range from a viscosity transition temperature of the LVT inorganic material to a metamorphic temperature of the material included in the intermediate layer of the organic light-emitting device.
